(19) United States
(12) Patent Application Publication
(10) Pub. No.: US 2010/0078310 A1
(43) Pub. Date: Apr. 1, 2010

(54) FABRICATING METHOD OF MAGNETORESISTIVE ELEMENT, AND STORAGE MEDIUM

(75) Inventors: Koji Tsunekawa, Tokyo (JP); Yoshinori Nagamine, Tokyo (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/483,704

(22) Filed: Jun. 12, 2009

(30) Foreign Application Priority Data
Sep. 30, 2008 (JP) 2008-252107
Mar. 26, 2009 (JP) 2009-076317

(51) Int. Cl. C23C 14/34

(52) U.S. Cl. 204/192.2

(57) ABSTRACT

The present invention provides a fabricating method of a magnetoresistive element having an MR ratio higher than a conventional MR ratio. In a step of depositing a magnetization fixed layer, a magnetization free layer, and a tunnel barrier layer on a substrate using a sputtering method in one embodiment of the present invention, the step of depositing the magnetization free layer deposits a ferromagnetic layer containing Co atoms, Fe atoms, and B atoms by a co-sputtering method using a first target containing Co atoms, Fe atoms and B atoms, and a second target having different B atom content from that of the first target.

### CROSS-REFERENCES TO RELATED APPLICATIONS

This application claims the benefit of priorities from Japanese Patent Application No. 2008-252107 filed Sep. 30, 2008 and Japanese Patent Application No. 2009-76317 filed Mar. 26, 2009, the entire contents of which is incorporated herein by reference.

### BACKGROUND OF THE INVENTION

1. Field of the Invention

The present invention relates to a fabricating method of a magnetoresistive element, preferably a tunneling magnetoresistive element (more preferably a spin-valve type tunneling magnetoresistive element), used for the magnetic reproducing head of a magnetic disk drive unit, the memory element of a magnetic random-access memory, and a magnetic sensor, and to a storage medium.

2. Related Background Art

Japanese Patent Application Laid-Open No. 2003-318465, International Publication No. WO2005/088745, Japanese Patent Application Laid-Open No. 2006-080116, US Patent Application No. 2006/0056115, D. D. Djayaprawira, et al., “Applied Physics Letters,” 86, 092502 (2005), C. L. Platt et al., “J. Appl. Phys.” 81(8), 15 Apr. 1997, W. H. Butler et al., “The American Physical Society” (Physical Review Vol. 63, 054416) 8, Jan. 2001, Shinji Yuasa et al., “Japanese Journal of Applied Physics” Vol. 43, No. 48, pp. 588-590, Apr. 2, 2004, and S. P. Parkin et al., “2004 Nature Publishing Group” Letters, pp. 862-887, Oct. 31 2004 describe a TMR (Tunneling Magneto Resistance)-effect element (hereinafter referred to as the TMR element) using a crystalline magnesium oxide film made of monocrystal or polycrystal as a tunnel barrier film.

### SUMMARY OF THE INVENTION

An object of the present invention is to provide a fabricating method of a magnetoresistive element (preferably a tunneling magnetoresistive element, more preferably a spin-valve type tunneling magnetoresistive element or the like) having a high MR ratio more improved than that of the related art, and a storage medium.

A first aspect of the present invention is a fabricating method of a magnetoresistive element comprising, on a substrate, a magnetization fixed layer, a magnetization free layer, and a tunnel barrier layer located between the magnetization fixed layer and the magnetization free layer, the method including the steps of: depositing the tunnel barrier layer on the magnetization fixed layer; and depositing the magnetization free layer on the tunnel barrier layer; wherein the step of depositing the magnetization free layer has a deposition step of depositing a ferromagnetic layer containing Co (cobalt) atoms, Fe (iron) atoms, and B (boron) atoms by a co-sputtering method using a first target containing Co (cobalt) atoms, Fe (iron) atoms, and B (boron) atoms, and a second target containing Co (cobalt) atoms and Fe (iron) atoms, the second target having different B (boron) atom content from that of the first target (however, the second target includes a case where B (boron) atom content is zero).

Furthermore, a second aspect of the present invention is a fabricating method of a magnetoresistive element comprising, on a substrate, a magnetization fixed layer, a magnetization free layer, and a tunnel barrier layer located between the magnetization fixed layer and the magnetization free layer, the method including the steps of: depositing the tunnel barrier layer on the magnetization fixed layer; and depositing the magnetization free layer on the tunnel barrier layer; wherein the step of depositing the magnetization free layer has: a deposition step of depositing an amorphous ferromagnetic layer containing Co (cobalt) atoms, Fe (iron) atoms, and B (boron) atoms by a co-sputtering method using a first target containing Co (cobalt) atoms, Fe (iron) atoms, and B (boron) atoms, and a second target containing Co (cobalt) atoms and Fe (iron) atoms, the second target having different B (boron) atom content from that of the first target (however, the second target includes a case where B (boron) atom content is zero); and a phase-change step of phase-changing the amorphous ferromagnetic layer to a crystalline ferromagnetic layer.

Still furthermore, a third aspect of the present invention is a storage medium for storing a control program configured to let a computer execute a fabricating method of a magnetoresistive element comprising, on a substrate, a magnetization fixed layer, a magnetization free layer, and a tunnel barrier layer located between the magnetization fixed layer and the magnetization free layer, the method including the steps of: depositing the tunnel barrier layer on the magnetization fixed layer; and depositing the magnetization free layer on the tunnel barrier layer; wherein the step of depositing the magnetization free layer has a deposition step of depositing a ferromagnetic layer containing Co (cobalt) atoms, Fe (iron) atoms, and B (boron) atoms by a co-sputtering method using a first target containing Co (cobalt) atoms, Fe (iron) atoms, and B (boron) atoms, and a second target containing Co (cobalt) atoms and Fe (iron) atoms, the second target having different B (boron) atom content from that of the first target (however, the second target includes a case where B (boron) atom content is zero).

Still furthermore, a fourth aspect of the present invention is a storage medium for storing a control program configured to let a computer execute a fabricating method of a magnetoresistive element comprising, on a substrate, a magnetization fixed layer, a magnetization free layer, and a tunnel barrier layer located between the magnetization fixed layer and the magnetization free layer, the method including the steps of: depositing the tunnel barrier layer on the magnetization fixed layer; and depositing the magnetization free layer on the tunnel barrier layer; wherein the step of depositing the magnetization free layer has: a deposition step of depositing an amorphous ferromagnetic layer containing Co (cobalt) atoms, Fe (iron) atoms, and B (boron) atoms by a co-sputtering method using a first target containing Co (cobalt) atoms, Fe (iron) atoms, and B (boron) atoms, and a second target containing Co (cobalt) atoms and Fe (iron) atoms, the second target having different B (boron) atom content from that of the first target (however, the second target includes a case where B (boron) atom content is zero); and a phase-change step of phase-changing the amorphous ferromagnetic layer to a crystalline ferromagnetic layer.

Still furthermore, a fifth aspect of the present invention is a storage medium for storing a control program configured to let a computer execute a fabricating method of a magnetoresistive element comprising, on a substrate, a magnetization fixed layer, a magnetization free layer, and a tunnel barrier layer located between the magnetization fixed layer and the magnetization free layer, the method including the steps of: depositing the magnetization fixed layer; depositing the tunnel barrier layer on the magnetization fixed layer; and depositing the magnetization free layer on the tunnel barrier layer; wherein both the step of depositing the magnetization fixed layer and the step of depositing the magnetization free layer have a deposition step of depositing a ferromagnetic layer containing Co (cobalt) atoms, Fe (iron) atoms, and B (boron) atoms by a co-sputtering method using a target containing Co (cobalt) atoms, Fe (iron) atoms, and B (boron) atoms, and another target containing Co (cobalt) atoms and Fe (iron) atoms, the another target having different B (boron) atom content from that of the target (however, the another target includes a case where B (boron) atom content is zero).

According to the present invention, it is possible to greatly improve an MR ratio achieved with a conventional TMR element.

### BRIEF DESCRIPTION OF THE DRAWINGS

FIG. 1 is a cross-sectional view of a magnetoresistive element of the present invention.

FIG. 2 is a schematic view of a manufacturing apparatus used for a magnetoresistive element of the present invention.

FIG. 3 is a block diagram of a manufacturing apparatus used for a magnetoresistive apparatus in accordance with the present invention.

FIG. 4 is a schematic perspective view of an MRAM in accordance with the present invention.

FIG. 5 is an equivalent circuit diagram of the MRAM in accordance with the present invention.

FIG. 6 is a cross-sectional view of another tunnel barrier layer of the present invention.

FIG. 7 is a schematic perspective view of a columnar crystal structure in accordance with the present invention.

FIG. 8 is a cross-sectional view of another TMR element of the present invention.

### DESCRIPTION OF THE PREFERRED EMBODIMENTS

Hereinafter, preferred embodiments (examples) of the present invention will be described according to the accompanying drawings.

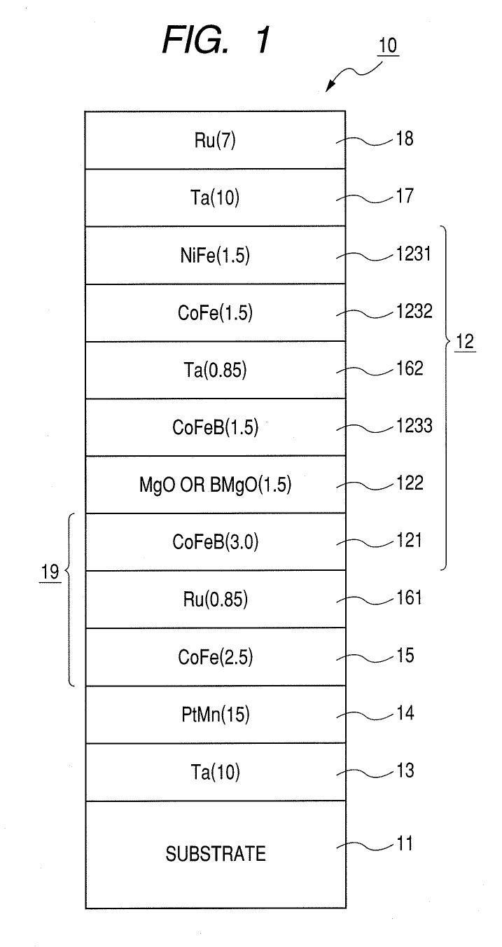

FIG. 1 illustrates one example of a laminated structure of a magnetoresistive element 10 in accordance with the present invention and, specifically, a laminated structure of the magnetoresistive element 10 using a TMR element 12. In this magnetoresistive element 10, the TMR element 12 is used to form a multilayer film comprising the TMR element 12, for example, having 12 layers, on a substrate 11. This 12-layer multilayer film has a multilayer film structure in which the layers are laminated in order from the lowermost first layer made of “Ta (tantalum)” to the uppermost 12th layer made of “Ru (ruthenium).”

As illustrated in FIG. 1, magnetic layers and nonmagnetic layers are laminated in the order of a nonmagnetic layer “Ta (10)” 13, an antiferromagnetic layer “PtMn (15)” 14, a ferromagnetic layer “CoFe (2.5)” 15, a nonmagnetic metal layer “Ru (0.85)” 161, a magnetic layer “CoFeB (3.0)” 121 which is a first ferromagnetic layer, a nonmagnetic multicrystal layer “MgO (1.5) or BMgO (1.5)” 122 which is a tunnel barrier layer, a multicrystal layer “CoFeB (1.5)” 1233 which is a second ferromagnetic layer, a nonmagnetic metal layer “Ta (0.85)” 162, multicrystal layers “CoFe (1.5)” 1232 and “NiFe (1.5)” 1231 which form a third ferromagnetic layer having a laminated film structure, a nonmagnetic layer “Ta (10)” 17, and a nonmagnetic layer “Ru (7)” 18. The “CoFeB (3.0)” layer 121 which is the first ferromagnetic layer and the “CoFeB (1.5)” multicrystal layer 1233 which is the second ferromagnetic layer can be deposited by a deposition method based on a co-sputtering method using two types of targets.

In addition, in the present invention, the first ferromagnetic layer may have a laminated structure having two or more layers, including the CoFeB layer 121 deposited by a deposition method based on the co-sputtering method using two types of targets and another ferromagnetic layer deposited by a deposition method based on a sputtering method using a single target. Also in the present invention, the “CoFe (1.5)” third ferromagnetic layer 1232 may be changed to a “CoFeB (1.5)” layer 1232 containing B (boron) atoms. Also in the present invention, the “NiFe (1.5)” third ferromagnetic layer 1231 may be changed to an NiFeB (1.5)” layer 1231 containing B (boron) atoms.

Reference numeral 11 denotes a substrate such as a wafer substrate, a glass substrate or a sapphire substrate. Reference numeral 12 denotes a TMR element. The TMR element 12 is formed into a six-layer laminated film structure having the first ferromagnetic layer 121 containing a multicrystal CoFeB (cobalt-iron-boron) alloy, the tunnel barrier layer 122 containing an MgO (magnesium oxide) or BMgO (boron magnesium oxide) multicrystal, the second ferromagnetic layer 1233 containing a multicrystal CoFeB (cobalt-iron-boron) alloy, the nonmagnetic Ta layer 162, and the third ferromagnetic layer which is a laminated film including a multicrystal CoFe (cobalt-iron) alloy and a multicrystal NiFe (nickel-iron) alloy (CoFe layer 1232 and NiCo layer 1231). The nonmagnetic layer 162 formed using a nonmagnetic metal, such as Ta (tantalum) or Ru (ruthenium), or a nonmagnetic insulator, such as Al₂O₃ (aluminum oxide), SiO₂ (silicon dioxide) or Si₂N₃ (silicon nitride), is interposed between the second ferromagnetic layer and the third ferromagnetic layer. According to the present invention, it is possible for the multicrystal CoFe (cobalt-iron) alloy used for the CoFe layer 1232 to contain an extremely small amount (5 atomic % or smaller, preferably 0.01 to 1 atomic %) of another type of atoms, for example, B (boron) or Pt (platinum) atoms. Reference numeral 13 denotes an underlying electrode layer (foundation layer) provided as the first layer (Ta (tantalum) layer) and reference numeral 14 denotes an antiferromagnetic layer provided as the second layer (PtMn layer). Reference numeral 15 denotes a ferromagnetic layer provided as the third layer (CoFe layer), reference numeral 161 denotes a nonmagnetic spacer layer for exchange coupling provided as the fourth layer (Ru layer).

The CoFeB layer 121 which is the fifth layer is deposited by a co-sputtering method using, for example, a CoFe alloy target having an atomic composition ratio of 70/30 and a CoFeB alloy target having an atomic composition ratio of 60/20/20, different from the former atomic composition ratio. The CoFeB layer 121 is then subjected to a subsequent annealing step performed at a temperature of 200 to 350° C. The CoFeB layer 121 immediately after deposition by the co-sputtering method is preferably amorphous, but may be one of a nanocrystal, a microcrystal (fine crystal) and a multicrystal. The amorphous CoFeB layer 121 is crystallized by an annealing step performed at a temperature of 200 to 350° C. Preferably, the amorphous CoFeB layer 121 can be phase-changed to one of a nanocrystal, a microcrystal (fine crystal) and a multicrystal.

In the present invention, targets are not limited to those having the above-described atomic composition ratios, but targets having atomic composition ratios selected as appropriate may be used. In particular, it is possible to use a combination of two types of targets having B (boron) atom contents different from each other. Examples of other combinations are as follows: As a first example, it is possible to use a combination of a CoFeB alloy target having an atomic composition ratio of 70/20/10 and a CoFeB alloy target having an atomic composition ratio of 60/20/20. Alternatively, as a second example, it is possible to use a combination of a CoFeB alloy target having an atomic composition ratio of 70/25/5 and a CoFeB alloy target having an atomic composition ratio of 50/25/25.

The boron content of the crystalline CoFeB layer 121 is set to within a range of 0.1 to 60 atomic %, preferably 10 to 50 atomic %. Furthermore, in the present invention, it is possible for the above-described two types of targets to contain an extremely small amount (5 atomic % or smaller, preferably 0.01 to 1 atomic %) of atoms other than CoFeB atoms, for example, Pt (platinum) atoms, Ni (nickel) atoms, or Mn (manganese) atoms.

In addition, the co-sputtering method of the present invention preferably sputters the two types of targets at the same time. Alternatively, the co-sputtering method may have a sputtering step performed at a point in time before or after this same point in time, using one of the two types of targets alone.

The layer having the third layer, the fourth layer and the fifth layer is a magnetization fixed layer 19. The magnetization fixed layer 19 in a substantial sense refers to a ferromagnetic layer which is the crystalline CoFeB layer 121 provided as the fifth layer. Reference numeral 122 denotes a tunnel barrier layer, which is an insulating layer, provided as the sixth layer (MgO: multicrystal magnesium oxide or BMgO: boron magnesium oxide). The tunnel barrier layer 122 used in the present invention may be a single multicrystal magnesium oxide or multicrystal boron magnesium oxide layer.

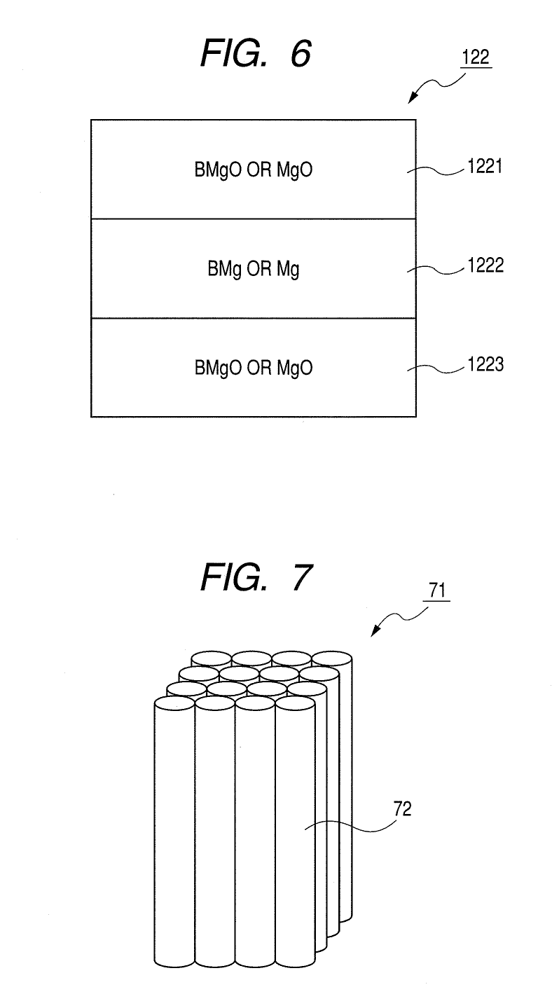

In addition, as illustrated in FIG. 6, the present invention can have a laminated structure having a multicrystal MgO (magnesium oxide) layer or multicrystal BMgO (boron magnesium oxide) layer 1221, a multicrystal Mg (metal magnesium) layer 1222, and a multicrystal MgO (magnesium oxide) layer or multicrystal BMgO (boron magnesium oxide) layer 1223. Alternatively, the present invention may have a laminated structure in which three layers having the laminated films 1221, 1222 and 1223 illustrated in FIG. 6 are provided in plurality.

The CoFeB layer 1233 which is a magnetization free layer provided as the seventh layer is deposited by a co-sputtering method using, for example, a CoFe alloy target having an atomic composition ratio of 70/30 and a CoFeB alloy target having an atomic composition ratio of 60/20/20, different from the former atomic composition ratio. The CoFeB layer 1233 is then subjected to a subsequent annealing step performed at a temperature of 200 to 350° C. The CoFeB layer 1233 immediately after deposition by the co-sputtering method is preferably amorphous, but may be one of a nanocrystal, a microcrystal (fine crystal) and a multicrystal. The amorphous CoFeB layer 1233 is crystallized by an annealing step performed at a temperature of 200 to 350° C. Preferably, the amorphous CoFeB layer 1233 can be phase-changed to one of a nanocrystal a microcrystal (fine crystal) and a multicrystal.

In the present invention, targets are not limited to those having the above-described atomic composition ratios, but targets having atomic composition ratios selected as appropriate may be used. In particular, it is possible to use a combination of two types of targets having B (boron) atom contents different from each other. Examples of other combinations are as follows: As a first example, it is possible to use a combination of a CoFeB alloy target having an atomic composition ratio of 70/20/10 and a CoFeB alloy target having an atomic composition ratio of 60/20/20. Alternatively, as a second example, it is possible to use a combination of a CoFeB alloy target having an atomic composition ratio of 70/25/5 and a CoFeB alloy target having an atomic composition ratio of 50/25/25.

The boron content of the crystalline CoFeB layer 1233 is set to within a range of 0.1 to 60 atomic %, preferably 10 to 50 atomic %. Furthermore, in the present invention, it is possible for the above-described two types of targets to contain an extremely small amount (5 atomic % or smaller, preferably 0.01 to 1 atomic %) of atoms other than CoFeB, for example, Pt (platinum), Ni (nickel), or Mn (manganese).

In addition, the co-sputtering method of the present invention preferably sputters the two types of targets at the same time. Alternatively, the co-sputtering method may have a sputtering step performed at a point in time before or after this same point in time, using one of the two types of targets alone.

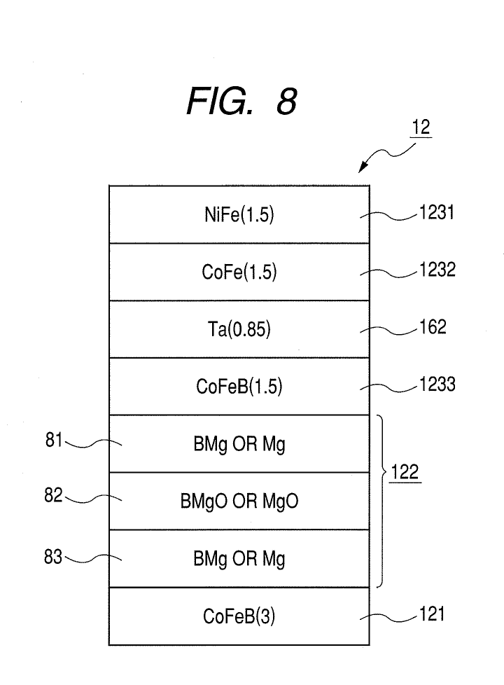

FIG. 8 illustrates an example of another TMR element 12 of the present invention. Reference numerals 12, 121, 122, 1231, 1232 and 1233 in FIG. 8 refer to the same members as those denoted by like reference numerals. In the present embodiment, the tunnel barrier layer 122 is a laminated film having a multicrystal MgO (magnesium oxide) or multicrystal BMgO (boron magnesium oxide) layer 82 and Mg (metal magnesium) or BMg (boron-magnesium alloy) layers 81 and 83 located on one and the other side of the layer 82.

In addition, in the present invention, the layer 81 may be excluded from use and the layer 82 can be located adjacent to the crystalline CoFeB layer 1233. Alternatively, the layer 83 may be excluded from use and the layer 82 can be located adjacent to the crystalline CoFeB layer 121.

FIG. 7 is a schematic perspective view of a multicrystal structure having an aggregate of columnar crystals 72 of a multicrystal MgO (magnesium oxide) layer. Also for a BMgO (boron magnesium oxide) layer, there was observed an aggregate similar to an aggregate 71 having columnar crystals 72 illustrated in FIG. 7.

The columnar crystal 72 is a conception that encompasses the conception of an acicular crystal, a columnar crystal, or the like. Alternatively, the crystal structure may be a structure having a multicrystal-amorphous mixed region, including a partial amorphous region between aggregates 71 of columnar crystals 72 in part of a multicrystal region.

The columnar crystal of a magnesium oxide or a boron magnesium oxide used in the present invention is preferably a single crystal in which a (001) crystal face is preferentially oriented in a film thickness direction in each column.

In addition, the BMgO (boron magnesium oxide) used in the present invention is represented by a general formula BₓMg_{y}O_{z} (where 0.7≦Z/[X+Y]≦1.3, preferably 0.8≦Z/[X+Y]<1.0). In the present invention, it is preferable to use stoichiometrical BMgO (boron magnesium oxide). Even if oxygen-deficient BMgO (boron magnesium oxide) is used, however, it is possible to obtain a high MR ratio.

In addition, the MgO (magnesium oxide) used in the present invention is represented by a general formula Mg_{y}O_{z} (where 0.7≦Z/Y≦1.3, preferably 0.8≦Z/Y<1.0). In the present invention, it is preferable to use stoichiometrical MgO (magnesium oxide). Even if oxygen-deficient MgO (magnesium oxide) is used, however, it is possible to obtain a high MR ratio.

The seventh layer, the ninth layer, and the tenth layer, respectively, are a ferromagnetic layer including the crystalline CoFeB layer 1233, a ferromagnetic layer including the crystalline CoFe layer 1232, and a ferromagnetic layer including the NiFe layer 1231. The laminated film having the seventh layer, the ninth layer and the tenth layer can function as a magnetization free layer. A Ta (tantalum) layer 162 for the eighth layer, which is a nonmagnetic metal layer, is located between the seventh layer and the ninth layer. For the eighth layer, it is possible to use a nonmagnetic metal, such as Ru (ruthenium) or Ir (iridium), or a nonmagnetic insulator, such as Al₂O₃ (aluminum oxide), SiO₂ (silicon dioxide) or Si₃N₄ (silicon nitride), in addition to the Ta (tantalum) layer 162. The film thickness of the eighth layer can be set to 50 nm or smaller, preferably within a range of 0.1 nm to 40 nm. The crystalline CoFeB layer 1233 constituting the seventh layer can be deposited by sputtering using a CoFeB alloy target. The crystalline CoFe layer 1232 constituting the ninth layer can be deposited by sputtering using a COFe alloy target. The crystalline NiFe layer 1231 constituting the tenth layer can be deposited by sputtering using an NiFe alloy target.

The crystalline CoFeB layer 121, the CoFeB layer 1233, the CoFe layer 1232 and the NiFe layer 1231 may have the same crystal structure as that of the aggregate 71 having columnar crystal structures 72 illustrated in FIG. 7. The crystalline CoFeB layer 121 and the CoFeB layer 1233 are preferably provided adjacent to the tunnel barrier layer 122 located between the layers 121 and 1233. In a manufacturing apparatus, these three layers are sequentially laminated without breaking the vacuum. Reference numeral 17 denotes an electrode layer provided as the eleventh layer (Ta: tantalum). Reference numeral 18 denotes a hard mask layer provided as the twelfth layer (Ru: ruthenium). The twelfth layer, if used as a hard mask, may be removed from a magnetoresistive element.

In FIG. 1, a numeric value in the parentheses of each layer shows the thickness of the layer, the unit of which is “nm (nanometer).” The thicknesses are examples only and not limited to these values.

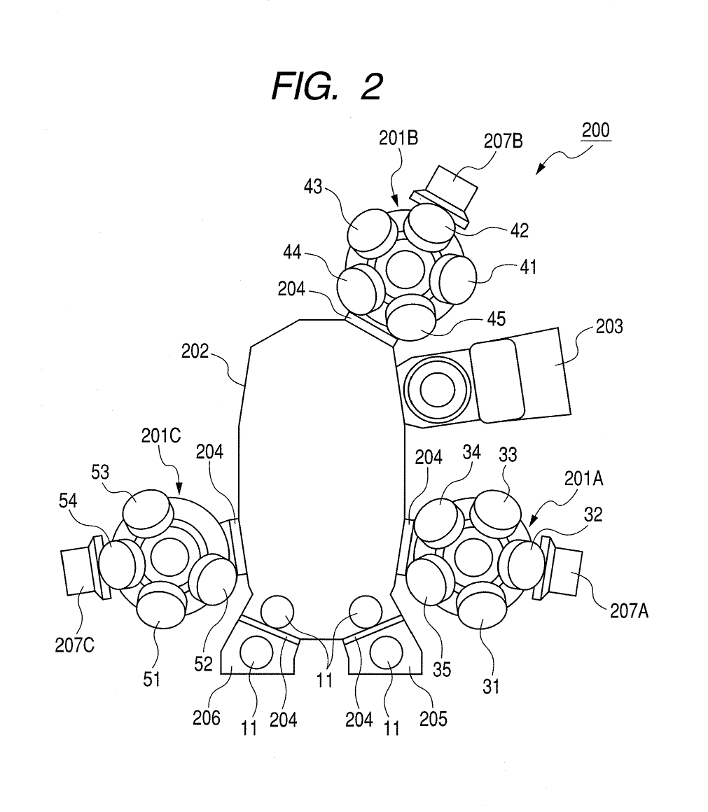

Next, an apparatus for fabricating a magnetoresistive element 10 having the above-described laminated structure and a method for fabricating the magnetoresistive element 10 will be described with reference to FIG. 2. FIG. 2 is a schematic plan view of the apparatus for fabricating the magnetoresistive element 10. The apparatus can fabricate a multilayer film containing a plurality of magnetic layers and a plurality of nonmagnetic layers, and is a mass production type sputtering deposition apparatus.

A magnetic multilayer film manufacturing apparatus 200 illustrated in FIG. 2 is a cluster type manufacturing apparatus and is provided with three deposition chambers based on a sputtering method. In the apparatus 200, a conveyance chamber 202 provided with an unillustrated robot conveyance apparatus is installed in the central position of the apparatus 200. In the conveyance chamber 202 of the manufacturing apparatus 200 for manufacturing a magnetoresistive element, there are provided two lock chambers, i.e., a load lock chamber 205 and an unload lock chamber 206, whereby a substrate (for example, a silicon substrate is used) 11 is carried in and out. Thus, the apparatus 200 is configured so that the load lock and unload lock chambers 205 and 206 alternately carry the substrate in and out, thereby reducing a tact time and manufacturing a magnetoresistive element with improved productivity.

In the manufacturing apparatus 200 for manufacturing a magnetoresistive element, three magnetron sputtering chambers for deposition 201A, 201B and 201C and one etching chamber 203 are provided around the conveyance chamber 202. In the etching chamber 203, a desired surface of the magnetoresistive element 10 is etching-treated. A freely openable and closable gate valve 204 is provided between each of the chambers 201A, 201B, 201C and 203 and the conveyance chamber 202. To each of the chambers 201A, 201B, 201C and 202, there are attached an unillustrated evacuation mechanism, a gas introduction mechanism, a power supply mechanism, and the like.

The manufacturing apparatus 200 for manufacturing a magnetoresistive element is provided with the magnetron sputtering chambers for deposition 201A, 201B and 201C. In each of these chambers 201A, 201B and 201C, it is possible to sequentially deposit the first to ninth layers on the substrate 11 using a high-frequency sputtering method, without breaking the vacuum. On the ceilings of the magnetron sputtering chambers for deposition 201A, 201B and 201C, there are respectively disposed four or five cathodes, i.e., cathodes 31, 32, 33, 34 and 35, cathodes 41, 42, 43, 44 and 45, and cathodes 51, 52, 53 and 54 arranged on appropriate circumferences of the ceilings. In addition, substrates 11 are placed on substrate holders positioned coaxially with the circumferences.

The magnetron sputtering apparatus is preferably such that targets are attached to the cathodes 31, 32, 33, 34 and 35, cathodes 41, 42, 43, 44 and 45, and cathodes 51, 52, 53 and 54 and magnets are disposed at the back of the attached targets.

In addition, high-frequency power such as radio-frequency (RF) power is applied from power supply means 207A, 207B and 207C to the above-described cathodes. As the high-frequency power, it is possible to use a frequency within a range of 0.3 MHz to 10 GHz, preferably 5 MHz to 5 GHz, and power within a range of 10 W to 500 W, preferably 100 W to 300 W.

In the foregoing discussion, for example, a Ta (tantalum) target is attached to the cathode 31. A PtMn (platinum-manganese alloy) target is attached to the cathode 32. A CoFeB target is attached to the cathode 33. A CoFe (cobalt-iron alloy) target is attached to the cathode 34. An Ru (ruthenium) target is attached to the cathode 35. The CoFeB layer 121 can be deposited by a co-sputtering method using two types of targets, i.e., the CoFeB target attached to the cathode 33 and the CoFe target attached to the cathode 34.

An MgO (magnesium oxide alloy) target is attached to the cathode 51. A BMgO (boron magnesium oxide) target is attached to the cathode 52. In addition, an Mg (metal magnesium) target is attached to the cathode 53, and BMg (boron-magnesium alloy) target is attached to the cathode 54. A TMR element 122 having the structure illustrated in FIG. 8 can be fabricated using this cathode 53 or 54.

A CoFe (cobalt-iron alloy) target for the seventh and ninth layers is attached to the cathode 41. A CoFeB (cobalt-iron-boron alloy) target for the seventh layer fabricated by using a co-sputtering method is attached to the cathode 42. A Ta (tantalum) target for the eighth and eleventh layers is attached to the cathode 43. An Ru (ruthenium) target for the twelfth layer is attached to the cathode 44. An NiFe (nickel iron) target for the tenth layer is attached to the cathode 45. The CoFeB layer 1233 can be deposited by a co-sputtering method using two types of targets, i.e., the CoFeB target attached to the cathode 42 and the CoFe target attached to the cathode 41.

The in-plane directions of the respective targets attached to the cathodes 31, 32, 33, 34 and 35, the cathodes 41, 42, 43, 44 and 45, and the cathodes 51, 52, 53 and 54 and the in-plane direction of a substrate are preferably arranged so as to be non-parallel to each other. By using the non-parallel arrangement, it is possible to sputter a target smaller in diameter than the substrate, while rotating the target. Accordingly, it is possible to deposit magnetic and nonmagnetic films having the same compositions as the compositions of targets with high efficiency. As an example of the above-described non-parallel arrangement, it is possible to arrange both in-plane directions non-parallel to each other, so that an intersecting angle formed by the central axis of each target and the central axis of the substrate is 45° or smaller, preferably 5° to 30°. In addition, as the rotational speed of the substrate at this time, it is possible to use 10 rpm to 500 rpm, preferably 50 rpm to 200 rpm.

Now, an explanation will be made of the deposition conditions of a TMR element 12 which is a principal element portion of the present invention. For the CoFeB layer 121, a CoFe target having a CoFe composition ratio (atomic ratio) of 70/30 and a target having a CoFeB composition ratio (atomic ratio) of 60/20/20 were used as simultaneous targets. For the CoFeB layer 121, Ar (argon gas) was used as a sputter gas and the pressure thereof was set to 0.03 Pa. The CoFeB layer 121 was deposited by magnetron DC sputtering (magnetron sputtering chamber for deposition 201A) at a deposition rate of 0.64 nm/sec. The CoFeB layer (CoFeB layer 121) at this time had an amorphous structure.

Subsequently, the apparatus was changed to a sputtering apparatus (magnetron sputtering chamber for deposition 201C), and an MgO target having an MgO composition ratio (atomic ratio) of 50/50 or a BMgO target having a BMgO composition ratio (atomic ratio) of 25/25/50 was used. Using Ar (argon gas) as the sputter gas and a pressure of 0.2 Pa, among pressures within a preferred pressure range of 0.01 to 0.4 Pa, a tunnel barrier layer 122 which was an MgO or BMgO layer for the sixth layer was deposited by magnetron RF sputtering (13.56 MHz). At this time, the MgO or BMgO layer (tunnel barrier layer 122) had a multicrystal structure having an aggregate 71 of columnar crystals 72 illustrated in FIG. 7. In addition, the deposition rate of magnetron RF sputtering (13.56 MHz) at this time was 0.14 nm/sec.

In the present invention, a crystalline (preferably, multicrystal) magnesium oxide layer can be obtained by depositing a crystalline (preferably, multicrystal) metal magnesium layer by a sputtering method using a metal magnesium-containing target and oxidizing the metal magnesium within an oxidization chamber (not shown in the figure) in which an oxidizing gas (oxygen gas, ozone gas, steam, or the like) has been introduced.

Also in the present invention, a crystalline (preferably, multicrystal) boron magnesium oxide layer can be obtained by depositing a crystalline (preferably, multicrystal) boron magnesium layer by a sputtering method using a boron-magnesium alloy-containing target and oxidizing the boron-magnesium alloy within an oxidization chamber (not shown in the figure) in which an oxidizing gas (oxygen gas, ozone gas, steam, or the like) has been introduced.

In the present embodiment, following on from the above-described step, the substrate was introduced into a sputtering apparatus (magnetron sputtering chamber for deposition 201B), and ferromagnetic layers which were magnetization free layers (CoFeB layer 1233 for the seventh layer, Ta layer 162 for the eighth layer, CoFe layer 1232 for the ninth layer and NiFe layer 1231 for the tenth layer) were deposited. For the CoFeB layer 1233, the CoFe layer 1232 and the NiFe layer 1231, Ar (argon gas) was used as a sputter gas and the pressure thereof was set to 0.03 Pa. The CoFeB layer 1233, the CoFe layer 1232 layer and the NiFe layer 1231 were deposited by magnetron DC sputtering (magnetron sputtering chamber for deposition 201B) at a sputter rate of 0.64 nm/sec. At this time, Ar (argon gas) was used as the sputter gas and the pressure thereof was set to 0.03 Pa for each of the CoFeB layer 1233, the CoFe layer 1232 layer and the NiFe layer 1231. In addition, targets having a CoFeB composition ratio (atomic) of 25/25/50, a CoFe composition ratio (atomic) of 50/50, and an NiFe composition ratio (atomic) of 40/60 were used. Immediately after this deposition, the CoFeB layer 1233, the CoFe layer 1232 and the NiFe layer 1231 had an amorphous structure.

While in this embodiment, the deposition rate of MgO and BMgO films was 0.14 nm/sec, there is no problem even if the films are deposited at a rate ranging from 0.01 nm to 1.0 nm/sec.

Sputtering deposition was performed in the magnetron sputtering chambers for deposition 201A, 201B and 201C, respectively, to complete lamination. An annealing treatment was performed on the magnetoresistive element 10 in a heat treatment furnace. The annealing temperature and time of the element at this time were approximately 300° C. and four hours, and annealing was performed in a magnetic field of 8 kOe. As a result, it was confirmed that the CoFeB layer 121, the CoFeB layer 1233, the CoFe layer 1232 and the NiFe layer 1231 having an amorphous structure had a multicrystal structure having the aggregate 71 of columnar crystals 72 illustrated in FIG. 7. The annealing step enables the magnetoresistive element 10 to behave as a magnetoresistive element having an TMR effect. It was also confirmed that the annealing step had imparted predetermined magnetism to an antiferromagnetic layer 14 which was a PtMn layer for the second layer.

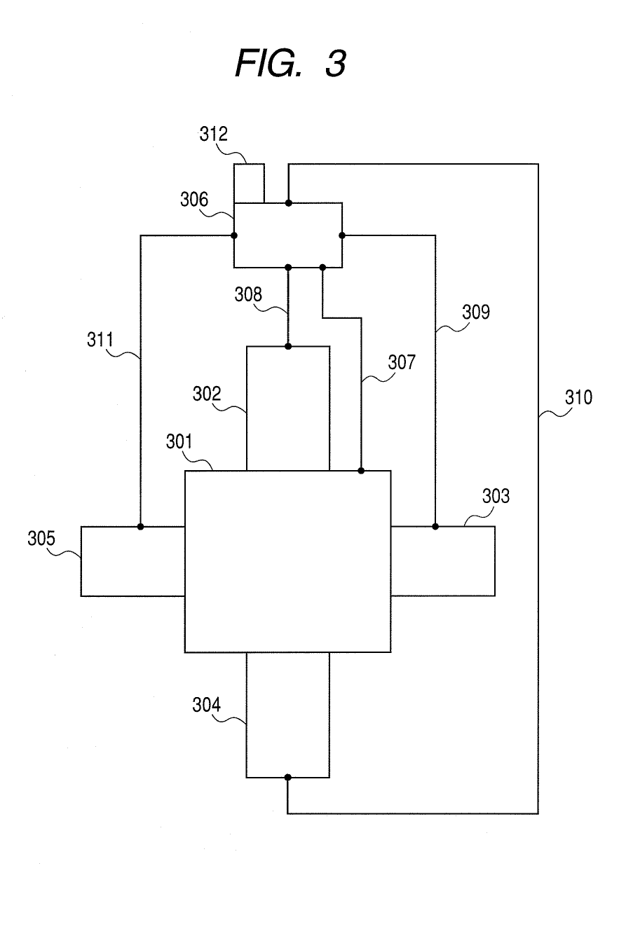

FIG. 3 is a block diagram of a manufacturing apparatus in accordance with the present invention. In the figure, reference numeral 301 denotes a conveyance chamber corresponding to the conveyance chamber 202 of FIG. 2, reference numeral 302 denotes a deposition chamber corresponding to the magnetron sputtering chamber for deposition 201A, reference numeral 303 denotes a deposition chamber corresponding to the magnetron sputtering chamber for deposition 201B, reference numeral 304 denotes a deposition chamber corresponding to the magnetron sputtering chamber for deposition 201C, reference numeral 305 denotes a load lock and unload lock chamber corresponding to the load lock and unload lock chambers 205 and 206, and reference numeral 306 denotes a central processing unit (CPU) containing a storage medium 312. Reference numerals 309 to 311 denote bus lines for interconnecting the CPU 306 with the respective processing chambers 301 to 305. Control signals for controlling the operation of the respective processing chambers 301 to 305 are transmitted from the CPU 306 to the respective processing chambers 301 to 305 through the bus lines.

In the first embodiment of the present invention, a substrate (not shown in the figure) within the load lock and unload lock chamber 305 is carried out to the conveyance chamber 301. In this step of carrying out the substrate, the CPU 306 performs a calculation on the basis of a control program stored in the storage medium 312 as a computer-executable program. The CPU 306 transmits a control signal based on the results of this calculation to various apparatus (for example, an unillustrated gate valve, robot mechanism, conveyance mechanism and driving system) mounted on the load lock and unload lock chamber 305 and the conveyance chamber 301 through the bus lines 307 and 311. That is, the above-described step of carrying out the substrate is performed as the result that the CPU 306 controls the execution of the above-described various apparatus using the control signal.

The substrate carried to the conveyance chamber 301 is carried out to the deposition chamber 302. Here, the first layer (Ta layer 13), the second layer (PtMn layer 14), the third layer (CoFe layer 15), the fourth layer (Ru layer 161) and the fifth layer (CoFeB layer 121) illustrated in FIG. 1 are sequentially laminated on the substrate carried in to the deposition chamber 302. At this stage, the CoFeB layer 121 which is the fifth layer has preferably an amorphous structure. In another embodiment, the CoFeB layer 121 at this stage may have a multicrystal structure.

In the process of laminating the above-described first to fifth layers, a control signal calculated within the CPU 306 on the basis of the control program stored in the storage medium 312 is transmitted through the bus lines 307 and 308 to various apparatus (for example, an unillustrated mechanism of power supply to cathodes, substrate-rotating mechanism, gas introduction mechanism, exhaust mechanism, gate valve, robot mechanism, conveyance mechanism, and driving system) mounted on the conveyance chamber 301 and the deposition chamber 302. The various apparatus perform predetermined operations on the basis of the received control signal. That is, the process of laminating the first to fifth layers is performed as the result that the CPU 306 controls the execution of the various apparatus using the control signal.

The substrate comprising a laminated film having layers up to the fifth layer is temporarily returned to the conveyance chamber 301, and is then carried in to the deposition chamber 303. The deposition of a multicrystal magnesium oxide or multicrystal boron magnesium oxide layer 122 as the sixth layer on the amorphous CoFeB layer 121, which is the fifth layer, is executed within the deposition chamber 303.

In the deposition of the magnesium oxide or multicrystal boron magnesium oxide layer 122 for the sixth layer, the control signal calculated within the CPU 306 on the basis of the control program stored in the storage medium 312 is transmitted through the bus lines 307 and 309 to various apparatus (for example, an unillustrated mechanism of power supply to cathodes, substrate-rotating mechanism, gas introduction mechanism, exhaust mechanism, gate valve, robot mechanism, conveyance mechanism, and driving system) mounted on the conveyance chamber 301 and the deposition chamber 303. The various apparatus perform predetermined operations on the basis of the received control signal. That is, the deposition of the sixth layer is performed as the result that the CPU 306 controls the execution of the various apparatus using the control signal.

The substrate comprising a laminated film having layers up to the magnesium oxide or multicrystal boron magnesium oxide layer 122 for the sixth layer is once again temporarily returned to the conveyance chamber 301, and is then carried in to the deposition chamber 304.

Within the deposition chamber 304, the seventh layer (CoFeB layer 1233), the eighth layer (Ta layer 162), the ninth layer (CoFe layer 1232), the tenth layer (NiFe layer 1231), the eleventh layer (Ta layer 17) and the twelfth layer (Ru layer 18) are sequentially laminated on the multicrystal magnesium oxide or multicrystal boron magnesium oxide layer 122 which is the sixth layer. At this stage, the CoFeB layer 1233 for the seventh layer, the CoFe layer 1232 for the ninth layer and the NiFe layer 1231 for the tenth layer preferably have an amorphous structure. In another embodiment, the CoFeB layer 1233 for the seventh layer, the CoFe layer 1232 for the ninth layer and the NiFe layer 1231 for the tenth layer at this stage may have a multicrystal structure.

In the process of laminating and depositing the above-described seventh (CoFeB layer 1232) to twelfth (Ru layer 18) layers, a control signal calculated within the CPU 306 on the basis of the control program stored in the storage medium 312 is transmitted through the bus lines 307 and 310 to various apparatus (for example, an unillustrated mechanism of power supply to cathodes, substrate-rotating mechanism, gas introduction mechanism, exhaust mechanism, gate valve, robot mechanism, conveyance mechanism, and driving system) mounted on the conveyance chamber 301 and the deposition chamber 304. The various apparatus perform predetermined operations on the basis of the received control signal. That is, the process of laminating and depositing the seventh (CoFeB layer 1232) to twelfth (Ru layer 18) layers is performed as the result that the CPU 306 controls the execution of the various apparatus using the control signal.

At this time, in the present embodiment, it is possible to deposit the Ta layer 162 which is the eighth layer and the Ta layer 17 which is the eleventh layer, using the same target attached to the cathode 43.

Examples of the storage medium 312 used in the present invention include computer-readable media, such a hard-disk medium, a magnetooptical-disk medium, a flexible-disk medium, and a general family of nonvolatile memories, including a flash memory and an MRAM, as well as media capable of storing programs.

In addition, in the present invention, the amorphous states of the fifth layer (CoFeB layer 121), the seventh layer (CoFeB layer 1233), the ninth layer (CoFe layer 1232) and the tenth layer (NiFe layer 1231) immediately after deposition can be changed to the multicrystal structure illustrated in FIG. 7 by annealing. Accordingly, in a fabrication method of the present invention, the magnetoresistive element 10 immediately after deposition is carried in to an annealing furnace (not shown in the figure), where the amorphous states of the fifth layer (CoFeB layer 121), the seventh layer (CoFeB layer 1233), the ninth layer (CoFe layer 1231) and the tenth layer (NiFe layer 1231) can be phase-changed to crystalline states. At this time, it is also possible to impart magnetism to the PtMn layer 14 which is the second layer. In the storage medium 312, it is possible to store a control program for performing steps in the annealing furnace. Using a control signal obtained by performing calculations based on the control program, the CPU 306 can control various apparatus within the annealing furnace (for example, a heater mechanism, an exhaust mechanism, and a conveyance mechanism, though not shown in the figure), and perform an annealing step.

As a comparative example of the present invention, a magnetoresistive element was fabricated using the same method as used in the first embodiment, except that the Ta layer 162 for the eighth layer, the CoFe layer 1232 for the ninth layer and the NiFe layer 1231 for the tenth layer were excluded from use.

Measurement of and comparison between the MR ratios of the magnetoresistive element fabricated in the first embodiment of the present invention and the above-described magnetoresistive element for comparison showed that the MR ratio of the magnetoresistive element of the first embodiment improved by a factor of 1.2 to 1.5 or greater, compared with the MR ratio of the magnetoresistive element for comparison.

Note that the MR ratio refers to a parameter related to a phenomenon (“Magneto-Resistive effect”) in which the electrical resistance of a magnetic film or a magnetic multilayer film also changes as the magnetization direction of the films changes in response to an external magnetic field. The rate of change in the electrical resistance is defined as the rate of change in magnetic resistance (MR ratio).

In the second embodiment of the present invention, a magnetoresistive element was fabricated in completely the same way as in the first embodiment, except that a multicrystal boron magnesium oxide layer was used as the sixth layer in place of the multicrystal magnesium oxide layer for the sixth layer used in the first embodiment. Measurement of the MR ratio of the fabricated magnetoresistive element showed that there was obtained an even more remarkably improved MR ratio (1.5 times or more higher than the MR ratio obtained in the embodiment in which the multicrystal magnesium oxide layer was used), compared with the embodiment in which the multicrystal magnesium oxide layer was used.

Furthermore, in the third embodiment of the present invention, a magnetoresistive element was fabricated using completely the same method as used in the first embodiment, except that the target of the CoFeB layer 121 for the fifth layer was changed to a single CoFeB (atomic composition ratio: 50/30/20) target. In the third embodiment, an advantageous effect similar to that of the first embodiment was obtained (the CoFeB 1233 layer which was a magnetization free layer for the seventh layer was deposited using the same co-sputtering method as used in the first embodiment).

Still furthermore, in the fourth embodiment of the present invention, a magnetoresistive element was fabricated using completely the same method as used in the first embodiment, except that CoFe layer 1232 for the ninth layer was changed to a CoFeB (atomic composition ratio: 50/30/20) layer. In the fourth embodiment, an advantageous effect similar to that of the first embodiment was obtained.

Still furthermore, in the fifth embodiment of the present invention, a magnetoresistive element was fabricated using completely the same method as used in the first embodiment, except that the NiFe layer 1231 for the tenth layer was changed to an NiFeB (atomic composition ratio: 50/30/20) layer. In the fifth embodiment, an advantageous effect similar to that of the first embodiment was obtained.

Still furthermore, in the sixth embodiment of the present invention, a magnetoresistive element was fabricated using completely the same method as used in the first embodiment, except that the MgO layer 122 for the sixth layer was changed to a BMgO layer 122. In the sixth embodiment, there was achieved an improvement greater by a factor 1.5 or more than the result of the first embodiment.

Still furthermore, as a second comparative example, a magnetoresistive element was fabricated using completely the same method as used in the first embodiment, except that the CoFeB layer 1233 which was a magnetization free layer and the CoFeB layer 121 which was a magnetization fixed layer were deposited by a sputtering method using a single CoFeB (atomic composition ratio: 60/20/20) target. Measurement of the MR ratio of the magnetoresistive element fabricated in this comparative example showed a result extremely as low as less than half the MR ratio obtained with the magnetoresistive element of the first embodiment.

As described above, in the present invention, the ferromagnetic layer (reference numeral 1233 in FIG. 1) which is a magnetization free layer is deposited by a co-sputtering method using two targets different at least in the composition ratio of B (boron) atoms from each other. Accordingly, as is understood from the third embodiment or the second comparative example in particular, it is possible to fabricate a magnetoresistive element having an even higher MR ratio.

Also, in the present invention, it is possible to use a crystalline ferromagnetic layer, such as a CoFeTaZr (cobalt-iron-tantalum-zirconium) alloy layer, a CoTaZr (cobalt-tantalum-zirconium) alloy layer, a CoFeNbZr (cobalt-iron-niobium-zirconium) alloy layer, a CoFeZr (cobalt-iron-zirconium) alloy layer, an FeTaC (iron-tantalum-carbon) alloy layer, an FeTaN (iron-tantalum-nitrogen) alloy layer, or an FeC (iron-carbon) alloy layer, in place of the CoFeB layer 121 for the fifth layer.

Also, in the present invention, it is possible to use an Rh (rhodium) layer or an Ir (iridium) layer in place of the Ru (ruthenium) layer for the fourth layer 161.

Also, in the present invention, an IrMn (iridium-manganese alloy) layer, an IrMnCr (iridium-manganese-chromium alloy) layer, an NiMn (nickel-manganese alloy) layer, a PdPtMn (lead-platinum-manganese alloy) layer, an RuRhMn (ruthenium-rhodium-manganese alloy) layer, an OsMn (osmium-manganese) layer, or the like is preferably used in place of the PtMn 14 (platinum-manganese alloy) layer for the second layer. In addition, the film thickness of the layer is preferably 10 to 30 nm.

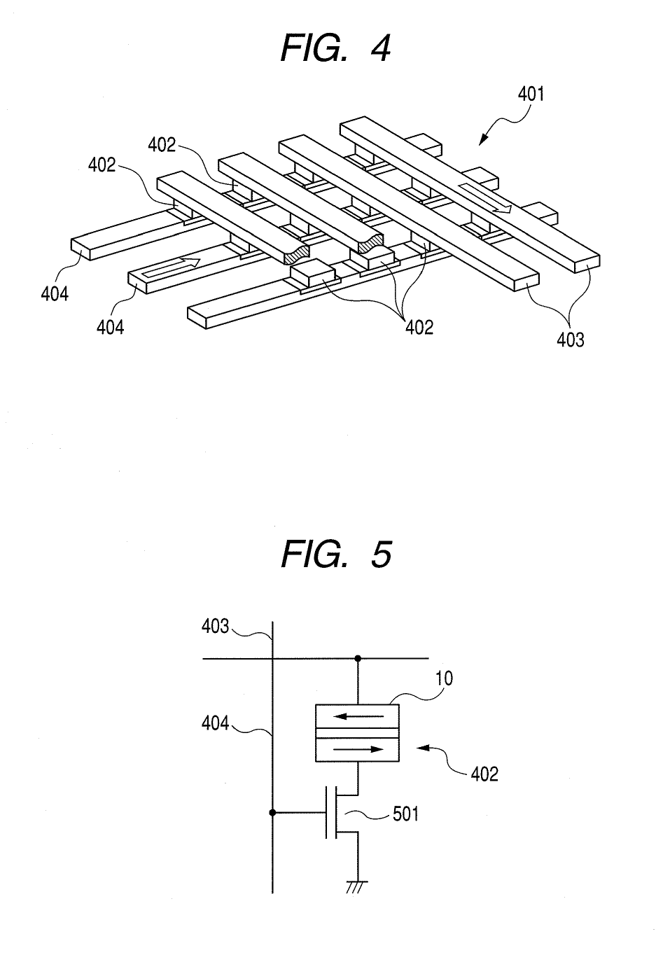

FIG. 4 is a schematic view of an MRAM (Magnetoresistive Random Access Memory, i.e., ferroelectric memory) 401 using a magnetoresistive element of the present invention as a memory element. In the MRAM 401, reference numeral 402 denotes the memory element of the present invention, reference numeral 403 denotes a word line, and reference numeral 404 denotes a bit line. Each of a multitude of memory elements 402 is located at each of intersection points between a plurality of word lines 403 and a plurality of bit lines 404. Thus, the memory elements are arranged in a lattice-like positional relationship with one another. Each of the multitude of memory elements 402 can store one bit of information.

FIG. 5 is an equivalent circuit diagram of the MRAM 401 configured by arranging a TMR element 10 for storing one bit of information and a transistor 501 having a switch function at an intersection point between a word line 403 and a bit line 404 of the MRAM 401.

The present invention can be applied as a memory element of an MRAM which is mass-producible, highly practical, and capable of ultrahigh integration.

What is claimed is:

1. A fabricating method of a magnetoresistive element comprising, on a substrate, a magnetization fixed layer, a magnetization free layer, and a tunnel barrier layer located between the magnetization fixed layer and the magnetization free layer, the method including the steps of:
depositing the tunnel barrier layer on the magnetization fixed layer; and
depositing the magnetization free layer on the tunnel barrier layer; wherein
the step of depositing the magnetization free layer has a deposition step of depositing a ferromagnetic layer containing Co (cobalt) atom, Fe (iron) atom, and B (boron) atom by co-sputtering method using a first target containing Co (cobalt) atom, Fe (iron) atom, and B (boron) atom, and a second target containing Co (cobalt) atom and Fe (iron) atom, the second target having different B (boron) atom content from that of the first target (however, the second target includes a case where B (boron) atom content is zero).

2. The fabricating method of a magnetoresistive element according to claim 1, wherein the step of depositing the tunnel barrier layer has a step of depositing a crystalline magnesium oxide layer by a sputtering method using a magnesium oxide-containing target.

3. The fabricating method of a magnetoresistive element according to claim 1, wherein the step of depositing the tunnel barrier layer has:
a deposition step of depositing a crystalline metal magnesium layer by a sputtering method using a metal magnesium-containing target; and
an oxidization step of oxidizing the crystalline metal magnesium layer into a crystalline magnesium oxide layer.

4. The fabricating method of a magnetoresistive element according to claim 1, wherein the step of depositing the tunnel barrier layer has a step of depositing a crystalline boron magnesium oxide layer by a sputtering method using a boron magnesium oxide-containing target.

5. The fabricating method of a magnetoresistive element according to claim 1, wherein the step of depositing the tunnel barrier layer has:
a deposition step of depositing a crystalline boron-magnesium alloy layer by a sputtering method using a boron-magnesium alloy-containing target; and
an oxidization step of oxidizing the crystalline boron-magnesium alloy layer into a crystalline boron magnesium oxide layer.

6. A fabricating method of a magnetoresistive element comprising, on a substrate, a magnetization fixed layer, a magnetization free layer, and a tunnel barrier layer located between the magnetization fixed layer and the magnetization free layer, the method including the steps of:
depositing the tunnel barrier layer on the magnetization fixed layer; and
depositing the magnetization free layer on the tunnel barrier layer; wherein
the step of depositing the magnetization free layer has:
a deposition step of depositing an amorphous ferromagnetic layer containing Co (cobalt) atoms, Fe (iron) atoms, and B (boron) atoms by a co-sputtering method using a first target containing Co (cobalt) atoms, Fe (iron) atoms, and B (boron) atoms, and a second target containing Co (cobalt) atoms and Fe (iron) atoms, the second target having different B (boron) atom content from that of the first target (however, the second target includes a case where B (boron) atom content is zero); and
a phase-change step of phase-changing the amorphous ferromagnetic layer to a crystalline ferromagnetic layer.

7. The fabricating method of a magnetoresistive element according to claim 6, wherein the phase-change step has an annealing step.

8. The fabricating method of a magnetoresistive element according to claim 6, wherein the step of depositing the tunnel barrier layer has a step of depositing a crystalline magnesium oxide layer by a sputtering method using a magnesium oxide-containing target.

9. The fabricating method of a magnetoresistive element according to claim 6, wherein the step of depositing the tunnel barrier layer has:
a deposition step of depositing a crystalline metal magnesium layer by a sputtering method using a metal magnesium-containing target; and
an oxidization step of oxidizing the crystalline metal magnesium layer into a crystalline magnesium oxide layer.

10. The fabricating method of a magnetoresistive element according to claim 6, wherein the step of depositing the tunnel barrier layer has a step of depositing a crystalline boron magnesium oxide layer by a sputtering method using a boron magnesium oxide-containing target.

11. The fabricating method of a magnetoresistive element according to claim 6, wherein the step of depositing the tunnel barrier layer has:
a deposition step of depositing a crystalline boron-magnesium alloy layer by a sputtering method using a boron-magnesium alloy-containing target; and
an oxidization step of oxidizing the crystalline boron-magnesium alloy layer into a crystalline boron magnesium oxide layer.

12. A storage medium for storing a control program configured to let a computer execute a fabricating method of a magnetoresistive element comprising, on a substrate, a magnetization fixed layer, a magnetization free layer, and a tunnel barrier layer located between the magnetization fixed layer and the magnetization free layer, the method including the steps of:
depositing the tunnel barrier layer on the magnetization fixed layer; and
depositing the magnetization free layer on the tunnel barrier layer; wherein
the step of depositing the magnetization free layer has a deposition step of depositing a ferromagnetic layer containing Co (cobalt) atoms, Fe (iron) atoms, and B (boron) atoms by a co-sputtering method using a first target containing Co (cobalt) atoms, Fe (iron) atoms, and B (boron) atoms, and a second target containing Co (cobalt) atoms and Fe (iron) atoms, the second target having different B (boron) atom content from that of the first target (however, the second target includes a case where B (boron) atom content is zero).

13. The storage medium according to claim 12, wherein the step of depositing the tunnel barrier layer has a step of depositing a crystalline magnesium oxide layer by a sputtering method using a magnesium oxide-containing target.

14. The storage medium according to claim 12, wherein the step of depositing the tunnel barrier layer has:
a deposition step of depositing a crystalline metal magnesium layer by a sputtering method using a metal magnesium-containing target; and
an oxidization step of oxidizing the crystalline metal magnesium layer into a crystalline magnesium oxide layer.

15. The storage medium according to claim 12, wherein the step of depositing the tunnel barrier layer has a step of depositing a crystalline boron magnesium oxide layer by a sputtering method using a boron magnesium oxide-containing target.

16. The storage medium according to claim 12, wherein the step of depositing the tunnel barrier layer has:
a deposition step of depositing a crystalline boron-magnesium alloy layer by a sputtering method using a boron-magnesium alloy-containing target; and
an oxidization step of oxidizing the crystalline boron-magnesium alloy layer into a crystalline boron magnesium oxide layer.

17. A storage medium for storing a control program configured to let a computer execute a fabricating method of a magnetoresistive element comprising, on a substrate, a magnetization fixed layer, a magnetization free layer, and a tunnel barrier layer located between the magnetization fixed layer and the magnetization free layer, the method including the steps of:
depositing the tunnel barrier layer on the magnetization fixed layer; and
depositing the magnetization free layer on the tunnel barrier layer; wherein
the step of depositing the magnetization free layer has:
a deposition step of depositing an amorphous ferromagnetic layer containing Co (cobalt) atoms, Fe (iron) atoms, and B (boron) atoms by a co-sputtering method using a first target containing Co (cobalt) atoms, Fe (iron) atoms, and B (boron) atoms, and a second target containing Co (cobalt) atoms and Fe (iron) atoms, the second target having different B (boron) atom content from that of the first target (however, the second target includes a case where B (boron) atom content is zero); and
a phase-change step of phase-changing the amorphous ferromagnetic layer to a crystalline ferromagnetic layer.

18. The storage medium according to claim 17, wherein the phase-change step has an annealing step.

19. The storage medium according to claim 17, wherein the step of depositing the tunnel barrier layer has a step of depositing a crystalline magnesium oxide layer by a sputtering method using a magnesium oxide-containing target.

20. The storage medium according to claim 17, wherein the step of depositing the tunnel barrier layer has:
a deposition step of depositing a crystalline metal magnesium layer by a sputtering method using a metal magnesium-containing target; and
an oxidization step of oxidizing the crystalline metal magnesium layer into a crystalline magnesium oxide layer.

21. The storage medium according to claim 17, wherein the step of depositing the tunnel barrier layer has a step of depositing a crystalline boron magnesium oxide layer by a sputtering method using a boron magnesium oxide-containing target.

22. The storage medium according to claim 17, wherein the step of depositing the tunnel barrier layer has:
a deposition step of depositing a crystalline boron-magnesium alloy layer by a sputtering method using a boron-magnesium alloy-containing target; and
an oxidization step of oxidizing the crystalline boron-magnesium alloy layer into a crystalline boron magnesium oxide layer.

23. A storage medium for storing a control program configured to let a computer execute a fabricating method of a magnetoresistive element comprising, on a substrate, a magnetization fixed layer, a magnetization free layer, and a tunnel barrier layer located between the magnetization fixed layer and the magnetization free layer, the method including the steps of:
depositing the magnetization fixed layer;
depositing the tunnel barrier layer on the magnetization fixed layer; and
depositing the magnetization free layer on the tunnel barrier layer; wherein
both the step of depositing the magnetization fixed layer and the step of depositing the magnetization free layer have a deposition step of depositing a ferromagnetic layer containing Co (cobalt) atoms, Fe (iron) atoms, and B (boron) atoms by a co-sputtering method using a target containing Co (cobalt) atoms, Fe (iron) atoms, and B (boron) atoms, and another target containing Co (cobalt) atoms and Fe (iron) atoms, the another target having different B (boron) atom content from that of the target (however, the another target includes a case where B (boron) atom content is zero).

24. The storage medium according to claim 23, wherein the step of depositing the tunnel barrier layer has a step of depositing a crystalline magnesium oxide layer by a sputtering method using a magnesium oxide-containing target.

25. The storage medium according to claim 23, wherein the step of depositing the tunnel barrier layer has:
a deposition step of depositing a crystalline metal magnesium layer by a sputtering method using a metal magnesium-containing target; and
an oxidization step of oxidizing the crystalline metal magnesium layer into a crystalline magnesium oxide layer.

26. The storage medium according to claim 23, wherein the step of depositing the tunnel barrier layer has a step of depositing a crystalline boron magnesium oxide layer by a sputtering method using a boron magnesium oxide-containing target.

27. The storage medium according to claim 23, wherein the step of depositing the tunnel barrier layer has:
a deposition step of depositing a crystalline boron-magnesium alloy layer by a sputtering method using a boron-magnesium alloy-containing target; and
an oxidization step of oxidizing the crystalline boron-magnesium alloy layer into a crystalline boron magnesium oxide layer.
